(19) United States
(12) Patent Application Publication
(10) Pub. No.: US 2026/0038547 A1
(43) Pub. Date: Feb. 5, 2026

(54) DATA PROCESSING APPARATUS, METHOD FOR PROCESSING DATA, AND COMPUTER-READABLE NON-TRANSITORY MEDIUM

(71) Applicant: PFU Limited, ISHIKAWA (JP)

(72) Inventors: Kensuke HASHIMOTO, ISHIKAWA (JP); Tomoaki WADA, ISHIKAWA (JP)

(21) Appl. No.: 19/261,182

(22) Filed: Jul. 7, 2025

(30) Foreign Application Priority Data
Aug. 2, 2024 (JP) 2024-127836

(51) Int. Cl. G11C 7/10; G06F 3/06; G06K 7/10

(52) U.S. Cl. CPC G11C 7/1006; G06F 3/0613; G06F 3/0683; G06K 7/10198

(57) ABSTRACT

A data processing apparatus includes circuitry to read a data segment and control information from each of multiple storage media. The data segment is obtained by splitting electronic data, and the control information indicates a concatenation sequence of the data. The circuitry concatenates the data segments individually read from the multiple storage media according to the concatenation sequence indicated in the control information to restore the electronic data.

### CROSS-REFERENCE TO RELATED APPLICATIONS

This patent application is based on and claims priority pursuant to 35 U.S.C. § 119(a) to Japanese Patent Application No. 2024-127836, filed on Aug. 2, 2024, in the Japan Patent Office, the entire disclosure of which is hereby incorporated by reference herein.

### BACKGROUND

The present disclosure relates to a data processing apparatus, a method for processing data, and a computer-readable non-transitory medium.

There are techniques for reading and writing electronic data from and to a storage medium. For example, an image forming apparatus includes a reader/writer to read information from a short-range wireless communication authentication device and write information to the short-range wireless communication authentication device, and obtains customization information from the short-range wireless communication authentication device via short-range wireless communication. The image forming apparatus then stores, for each user, log information of selections made on a customization screen in the short-range wireless communication authentication device, and updates the customization screen based on the customization information for each user, including the log information stored in the short-range wireless communication authentication device.

It is desired to enhance the convenience of reading and writing electronic data. For example, in the related art, it is assumed that the size of data stored in a short-range wireless communication authentication device is equal to or smaller than the storage capacity of the short-range wireless communication authentication device, and storing one item of electronic data in multiple storage media is not considered.

### SUMMARY

The data processing apparatus according to one aspect of the present disclosure includes circuitry to read a data segment and control information from each of multiple storage media. The data segment is obtained by splitting electronic data, and the control information indicates a concatenation sequence of the data. The circuitry concatenates the data segments individually read from the multiple storage media according to the concatenation sequence indicated in the control information to restore the electronic data.

The method for processing data according to another aspect of the present disclosure includes reading a data segment and control information from each of multiple storage media. The data segment is obtained by splitting electronic data, and the control information indicates a concatenation sequence of the data. The method further includes concatenating the data segments individually read from the multiple storage media according to the concatenation sequence indicated in the control information to restore the electronic data.

The computer-readable, non-transitory medium storing a computer program according to still another aspect of the present disclosure causes a computer-readable, non-transitory medium storing a computer program, wherein the computer program causes a data processing apparatus that read electronic data from multiple storage media, to execute a process. The process includes reading a data segment and control information from each of the multiple storage media. The data segment is obtained by splitting the electronic data, and the control information indicates a concatenation sequence of the data segment. The process includes concatenating the data segments read from the multiple storage media according to the concatenation sequence indicated in the control information to restore the electronic data.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a block diagram illustrating an overall configuration of a data processing system;

FIG. 2 is a block diagram illustrating a hardware configuration of a controller;

FIG. 3 is a block diagram illustrating a functional configuration of the controller illustrated in FIG. 2;

FIG. 4 is a diagram illustrating a data structure of a near field communication (NFC) card;

FIG. 5 is a flowchart of a writing process;

FIGS. 6A to 6F are diagrams each illustrating an export screen;

FIG. 7 is a flowchart of a reading process; and

FIGS. 8A to 8G are diagrams each illustrating an import screen.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

### Embodiments

One embodiment of the present disclosure is a data processing system that reads and writes electronic data to a storage medium. The data processing system stores one item of electronic data in one or more storage media and reads the electronic data from one or more storage media. For example, the data processing system transfers electronic data from a first device to a second device using one or more storage media. As another example, the data processing system backs up electronic data stored on one device using one or more storage media.

The electronic data may be setting data indicating the setting information of the electronic device. The electronic device includes office equipment, home appliances, or facility equipment. The electronic device may be, for example, a scanner. The electronic device is not limited to a scanner. Examples thereof include a printer, a facsimile machine, and a digital multifunctional peripheral (MFP).

The storage medium may be a portable storage medium. The storage medium may be a medium from or to which data is read or written via wireless communication. For example, the storage medium may be an integrated circuit (IC) card with an embedded IC chip. For example, the IC card may be a near field wireless communication (NFC) card that allows data to be written to an IC chip and data to be read from an IC chip. The storage medium is not limited to an NFC card. Examples thereof include a memory card having a memory element such as a flash memory and a universal serial bus (USB) memory.

Electronic data is read from or written to a storage medium for purposes such as data import/export or backup. When the size of electronic data is greater than the storage capacity of the storage medium, the electronic data is split and stored on multiple storage media. For example, the storage capacity of an NFC card is at most several kilobytes. NFC cards are used, for example, for personal authentication, and authentication information is stored in such cases. Although the storage capacity of an NFC card is sufficient for storing authentication information, it is insufficient for storing the setting data of an electronic device.

In some cases, office equipment, such as scanners, is deployed at multiple locations with the same settings. If one NFC card cannot store the entire setting data of the scanner, some items of the setting data, such as network setting data, may be stored in the NFC card. In this case, an NFC card storing the network setting data is packaged together with the scanner and delivered to each location, and a worker at each location transfers the network setting data from the NFC card to the scanner. Other setting data is distributed via the network.

The above-described operation enhances user convenience to a certain extent since the user imports only the network settings. The above operation, however, does not make the scanner usable immediately after the settings are imported from the NFC card. Further, the above operation is not applicable to a scanner not connected to a network. Accordingly, the above operation still has room for enhancing user convenience.

An aim of the present disclosure is to enhance the convenience of reading or writing electronic data from or to a storage medium. In one aspect of the present disclosure, multiple data segments split from electronic data and control information indicating the concatenation sequence of the data segment are read from the multiple storage media, and the multiple data segments read from the multiple storage media are concatenated according to the sequence indicated in the control information. According to one aspect of the present disclosure, since the electronic data is read from the storage media in any order, the convenience of reading or writing electronic data from or to the storage media is enhanced.

### Overall Configuration

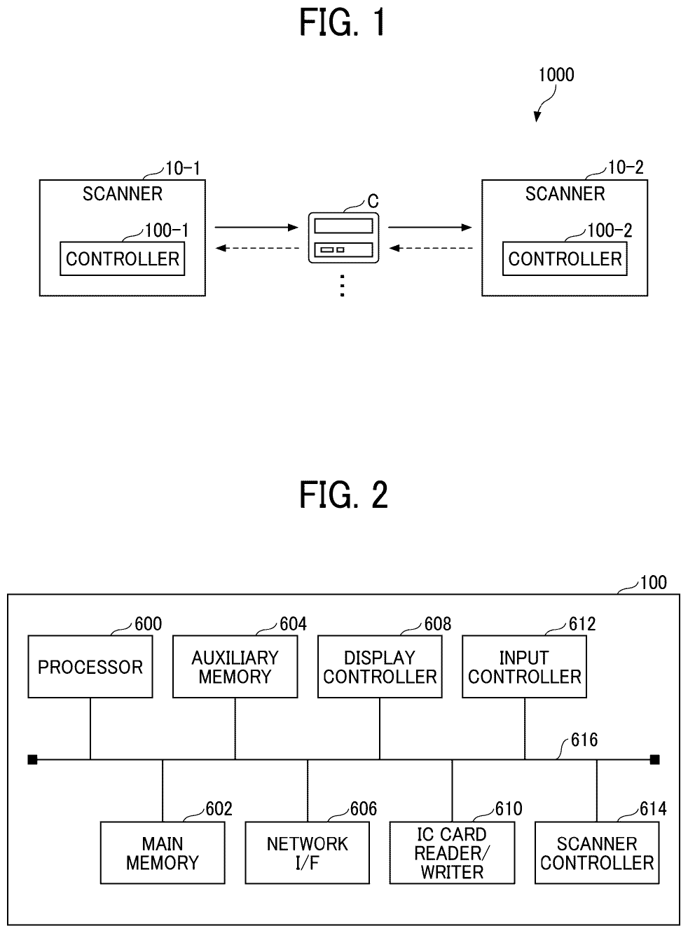

An overall configuration of a data processing system is described with reference to FIG. 1. FIG. 1 is a block diagram illustrating an overall configuration of a data processing system 1000.

As illustrated in FIG. 1, the data processing system 1000 includes two scanners 10 (10-1 and 10-2) and one or more near field communication (NFC) cards C. The scanner 10 is an example of an electronic device. The NFC card is an example of a storage medium.

In the following description, when there are multiple scanners 10, reference signs with suffixes are used for distinction, like “scanner 10-1” and “scanner 10-2.” When the term “scanner 10” without a suffix is used, the description thereof applies to all the scanners 10.

The scanner 10 is an example of an image reading apparatus that optically reads an image formed on an image forming medium. The scanner 10 may output image data read from an image forming medium. The scanner 10 may perform data processing such as optical character recognition (OCR) on the image data read from the image forming medium and output the processing result. The scanner 10 may transmit the image data or the processing result of the image data to an information processing apparatus, such as a personal computer or a server, via a communication network.

The scanner 10 includes a controller 100 built therein. In other words, the scanner 10-1 includes a built-in controller 100-1, and the scanner 10-2 includes a built-in controller 100-2. The controller 100 is an example of an information processing apparatus that controls the operation of the scanner 10. The controller 100 controls the scanning operation of the scanner 10 based on the setting data preliminarily stored in a memory.

The controller 100 has a function of importing and exporting setting data using an NFC card C. The controller 100-1 may write the setting data of the scanner 10-1 stored in the memory to one or more NFC cards C. The controller 100-2 may read the setting data of the scanner 10-1 from one or more NFC cards C and store the setting data in a memory as the setting data of the scanner 10-2. Thus, the data processing system 1000 can transfer the setting data of the scanner 10-1 to the scanner 10-2. The controller 100 is an example of a data processing apparatus.

Although transferring the setting data from the scanner 10-1 to the scanner 10-2 is described above, the scanner 10-1 or the scanner 10-2 may back up the setting data in the NFC card C. In this case, the data processing system 1000 may include one scanner 10 including the built-in controller 100. The controller 100 may write the setting data of the scanner 10 stored in the memory to an NFC card C. The controller 100 may read the setting data of the scanner 10 from the NFC card C and store the setting data in a memory.

The overall configuration of the data processing system 1000 illustrated in FIG. 1 is one example, and the system configuration may vary depending on the application or purpose. For example, the data processing system 1000 may include three or more scanners 10. For example, data processing system 1000 may include one scanner 10-1 and two or more scanners 10-2. This allows the setting data of the scanner 10-1 to be deployed to multiple scanners 10-2 via the NFC card C.

The controller 100 may be an information processing apparatus that is not built in the scanner 10 and communicates with the scanner 10 via a wired or wireless network. For example, the controller 100 may be an information processing terminal such as a personal computer, a smartphone, or a tablet terminal. When the controller 100 is implemented by an information processing terminal, the information processing terminal may include a built-in NFC module to read and write data from and to the NFC card C, or may include an external device interface (I/F) to connect to an NFC reader/writer that reads and writes data from and to an NFC card C.

### Hardware Configuration

The controller 100 included in the scanner 10 may be implemented by, for example, a computer. FIG. 2 is a block diagram illustrating a hardware configuration of the controller 100.

As illustrated in FIG. 2, the controller 100 includes a processor 600, a main memory 602, an auxiliary memory 604, a network interface (I/F) 606, a display controller 608, an integrated circuit (IC) card reader/writer 610, an input controller 612, and a scanner controller 614. The processor 600 and the main memory 602 together function as a so-called computer. The various hardware components of the controller 100 are connected to each other via a bus 616.

The processor 600 is an example of an arithmetic logic device that achieves the overall control and functions of the controller 100. The processor 600 may include, for example, a central processing unit (CPU) or a graphic processing unit (GPU). The processor 600 reads out programs and data from a memory such as the auxiliary memory 604 into the main memory 602 and executes the processes described in the programs.

The main memory 602 is an example of a memory that provides a work area for the processor 600 to execute a program. The main memory 602 may be a volatile semiconductor memory from which programs and data are erased when the power is turned off. The main memory 602 may include, for example, a dynamic random-access memory (DRAM) or a static random-access memory (SRAM).

The auxiliary memory 604 is an example of a non-volatile memory that stores programs and data. The auxiliary memory 604 may include, for example, a hard disk drive (HDD) or a solid-state drive (SSD). The programs stored in the auxiliary memory 604 may include basic software, such as an operating system (OS), for controlling the entire operation of the controller 100 and applications that provide various functions on the OS.

The display controller 608 is an example of a controller that controls a display device used to present various information to a user. The display device controlled by the display controller 608 may include, for example, a liquid crystal or organic electro-luminescence (EL) display.

The IC card reader/writer 610 is an example of a controller that reads and writes data from and to an IC card having an IC chip. The IC card reader/writer 610 may be, for example, an NFC module that reads or writes data by communicating with an IC chip embedded in an NFC card C via short-range wireless communication. The IC card reader/writer 610 may be implemented by an external NFC reader/writer that is externally connected to the controller 100 via any desired wired or wireless interface.

The input controller 612 is an example of a controller that controls an input device used by a user to input various information. The input device controlled by the input controller 612 may include, for example, a touch screen, operation keys, buttons, a keyboard, and a mouse.

The network I/F 606 is an interface for connecting to a communication network to perform data communication. The network I/F 606 may be connected to a communication network via various wired or wireless interfaces.

The scanner controller 614 is an example of a controller that controls the scanning operation of the scanner 10. In the scanning operation, the image forming medium placed on the media tray of the scanner 10 is fed to the conveying path as a conveyance roller rotates. Then, an image reader located near the conveying path images one or both sides of the image forming medium. The image captured by the image reader is subjected to image processing by a control circuit of the scanner 10, and image data representing the image formed on the image forming medium is generated.

For example, the various programs may be installed in the auxiliary memory 604 as follows. When a storage medium such as a compact disc (CD) or a digital versatile disc is set in a drive, the drive reads out from the storage medium the programs to be installed in the auxiliary memory 604. Alternatively, the various programs may be downloaded from a network via the network I/F 606 and installed in the auxiliary memory 604.

### Functional Configuration

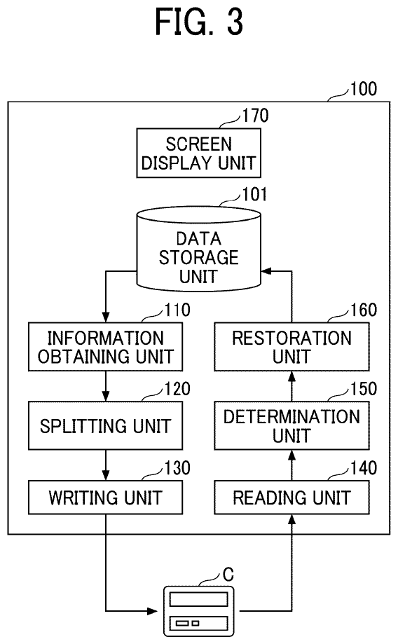

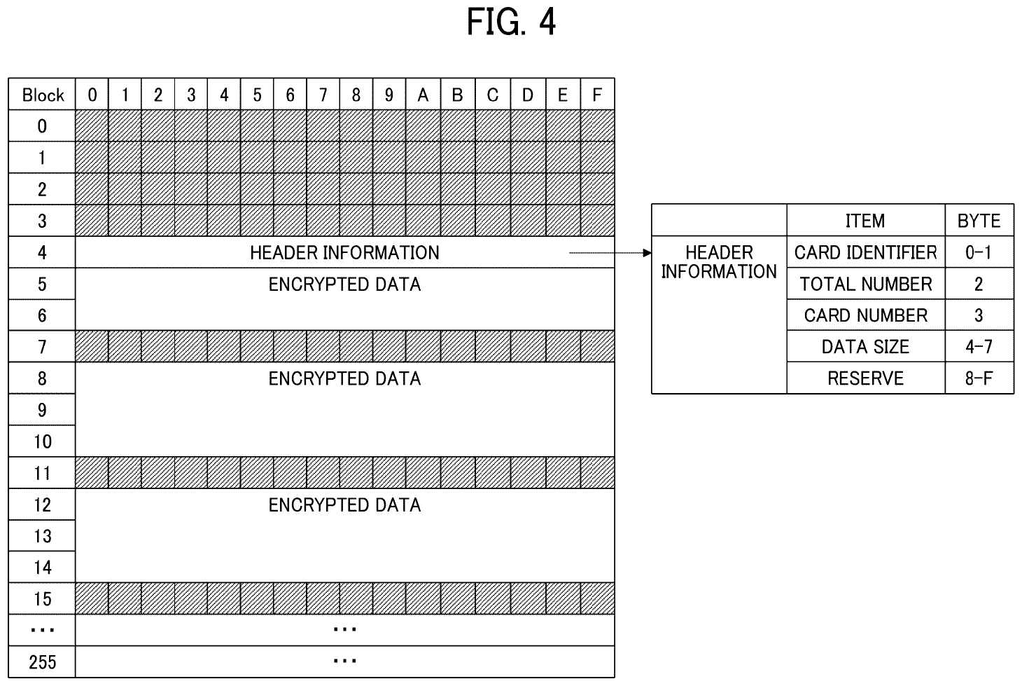

A functional configuration of the controller 100 included in the scanner 10 will be described with reference to FIGS. 3 and 4. FIG. 3 is a block diagram illustrating the functional configuration of the controller 100.

As illustrated in FIG. 3, the controller 100 includes a data storage unit 101, an information obtaining unit 110, a splitting unit 120, a writing unit 130, a reading unit 140, a determination unit 150, a restoration unit 160, and a screen display unit 170. The controller 100 functions as the data storage unit 101, the information obtaining unit 110, the splitting unit 120, the writing unit 130, the reading unit 140, the determination unit 150, the restoration unit 160, and the screen display unit 170 when a program installed in advance is executed.

For example, the data storage unit 101 is implemented by the auxiliary memory 604 illustrated in FIG. 2. For example, the information obtaining unit 110, the splitting unit 120, the writing unit 130, the reading unit 140, the determination unit 150, the restoration unit 160, and the screen display unit 170 are implemented by the processor 600 or the IC card reader/writer 610 executing a program loaded from the auxiliary memory 604 illustrated in FIG. 2 onto the main memory 602.

The data storage unit 101 stores setting data indicating setting information of the scanner 10. The setting data may be stored in advance in the data storage unit 101. The setting data may be generated by the input controller 612 when a user of the scanner 10 operates the input device.

The information obtaining unit 110 obtains information on the NFC card C and information on the setting data. The information obtaining unit 110 may obtain information indicating the storage capacity of the NFC card C. The information indicating the storage capacity may be the free space for additionally storing data on the NFC card C. The information obtaining unit 110 may obtain information indicating the size of the setting data.

The splitting unit 120 splits the setting data stored in the data storage unit 101 into multiple items of electronic data. In the following description, the portions of electronic data obtained by splitting the setting data will be referred to as “data segments.” The splitting unit 120 may split the setting data at equal data lengths, thereby splitting the setting data into multiple data segments. The splitting unit 120 may split the setting data into multiple data segments such that the size (data size) of each data segment is equal to or smaller than the storage capacity of the NFC card C.

The splitting unit 120 may perform desired data processing on the setting data when splitting the setting data into multiple data segments. The data processing may include, for example, at least one of compression and encryption.

The writing unit 130 writes (stores) the data segment to the NFC card C. The writing unit 130 repeatedly executes writing one data segment into one NFC card C for each of the multiple data segments split from the setting data by the splitting unit 120.

The writing unit 130 may perform desired data processing on the data segment when writing the data segment to the NFC card C. The data processing may include, for example, at least one of compression and encryption.

The writing unit 130 writes the data segment to the NFC card C in association with the control information. The control information is information used to control the reading and writing of data from and to the NFC card C. The control information includes information indicating the position of the data segment in the order of concatenation, which is referred to as “concatenation sequence information” in the following description. The concatenation sequence information may be numerical values individually assigned to the data segment in ascending order, from top, when the setting data is split into multiple data segments.

The control information may include information indicating the total number of NFC cards C storing the setting data. The information indicating the total number of NFC cards C may be information indicating the size of setting data. The total number of NFC cards Cis calculated by dividing the size of setting data by the storage capacity of the NFC cards C.

The control information may include identification information identifying a set of NFC cards C into which the setting data is written. The identification information may be unique information assigned each time the process of writing the setting data to the NFC card C is executed. In this case, even if the setting data is the same, different identification information is assigned when the NFC card C to which the setting data is written is different.

The control information may include information indicating the amount of data of the data segment. The control information is not limited to these items of information but may include various items of information for controlling the reading and writing of data from and to the NFC card C.

The reading unit 140 reads the data segment from the NFC card C. The reading unit 140 repeats reading one data segment from one NFC card C for each of the NFC cards C with the written setting data. The reading unit 140 reads from the NFC card C the data segment as well as the control information associated with the data segment.

The reading unit 140 repeats reading the data segment and the control information from the NFC card C until the data segment or the control information from the read NFC cards C satisfies a predetermined end condition. The end condition may be, for example, that the number of the NFC cards C read reaches the total number of NFC cards C designated by the control information. Alternatively, the end condition may be that the total data size of the data segments read from the read NFC cards C matches the size of the setting data indicated by the control information. Alternatively, the end condition may be that the data segment read from the read NFC card C contains an end symbol, such as an end of file (EOF) code.

The determination unit 150 determines whether to read data segment from the current NFC card C. The determination unit 150 may determine whether to read a data segment from the NFC card C based on the control information read from the current NFC card C.

For example, the determination unit 150 may determine not to read data segment from the current NFC card C when the concatenation sequence information in the control information read from the current NFC card C is not unique but overlaps the concatenation sequence information designated by the control information from the read NFC card C. Alternatively, the determination unit 150 may determine not to read a data segment from the current NFC card C when the identification information indicated by the control information read from the current NFC card C differs from the identification information indicated by the control information from the NFC card C already read.

The restoration unit 160 restores the setting data based on the multiple data segments read from the NFC cards C. The restoration unit 160 may restore the setting data based on the control information read from the NFC card C. The restoration unit 160 may restore the setting data by concatenating the data segments according to the concatenation sequence information in the control information.

The restoration unit 160 stores the setting data restored from the multiple data segments in the data storage unit 101. When the data storage unit 101 already stores the setting data, the restoration unit 160 may update the setting data in the data storage unit 101 with the restored setting data. The restoration unit 160 may allow the user to select whether to update the setting data in the data storage unit 101 with the restored setting data.

The screen display unit 170 displays an operation screen on a display device. The operation screen is a screen that receives operations related to the reading and writing of the NFC card C. The screen display unit 170 may receive an operation to start writing the setting data. The screen display unit 170 may receive an operation to start reading the setting data.

When writing the setting data to the NFC cards C, the screen display unit 170 may display, on the operation screen, the total number of NFC cards C to be used. The screen display unit 170 may display the information on the written NFC card C on the operation screen. The information on the written NFC card C may include information indicating the number of written NFC cards C. The information indicating the number of written NFC cards C may include the order of the currently written NFC card C. The screen display unit 170 may receive the input of authentication information for reading the setting data from the NFC card C.

In reading the setting data from the NFC cards C, the screen display unit 170 may display on the operation screen the total number of the NFC cards C with the written setting data. The screen display unit 170 may display the information on the read NFC card C on the operation screen. The information on the read NFC card C may include information indicating the number of read NFC cards C. The information indicating the number of read NFC cards C may include the order of the currently read NFC card C. The screen display unit 170 may receive the input of authentication information before reading the setting data from the NFC card C.

The functional configuration of the controller 100 illustrated in FIG. 3 is one example. Needless to say, the functional configuration may vary depending on the application or purpose. The manner of dividing the processing units, such as the data storage unit 101, the information obtaining unit 110, the splitting unit 120, the writing unit 130, the reading unit 140, the determination unit 150, the restoration unit 160, and the screen display unit 170 illustrated in FIG. 3, is one example.

For example, at least two of the information obtaining unit 110, the splitting unit 120, the writing unit 130, the reading unit 140, the determination unit 150, the restoration unit 160, and the screen display unit 170 may be integrated into one processing unit. Further, for example, at least one of the information obtaining unit 110, the splitting unit 120, the writing unit 130, the reading unit 140, the determination unit 150, the restoration unit 160, and the screen display unit 170 may be divided into multiple processing units. For example, the data storage unit 101 may be divided into multiple storage units.

FIG. 4 is a diagram illustrating a data structure of the NFC card C. As illustrated in FIG. 4, the NFC card C has a data structure in which multiple fixed-length blocks are arranged. In FIG. 4, the NFC card C includes 256 blocks, each of which has the storage capacity of 16 bytes.

In FIG. 4, the shaded areas are areas where writing is prohibited. The fourth block stores header information. The fifth to sixth blocks, the eighth to tenth blocks, the twelfth to fourteenth blocks, etc., store encrypted data. The encrypted data is an example of the data segment.

The header information includes the control information. The header information further includes a card identifier, a total number of cards, a card number, and a data size. The card identifier is an example of identification information identifying a set of NFC cards C with written setting data. The total number is an example of information indicating the total number of multiple NFC cards C with written setting data. The card number is an example of the concatenation sequence information of the data segment written to the NFC card C. The data size is an example of information indicating the amount of data of the data segments written to the NFC card C.

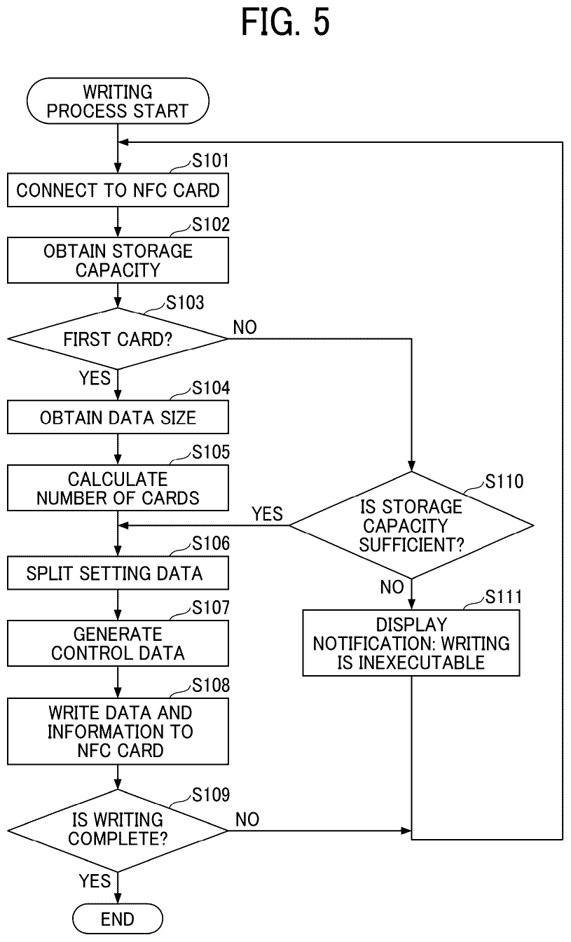

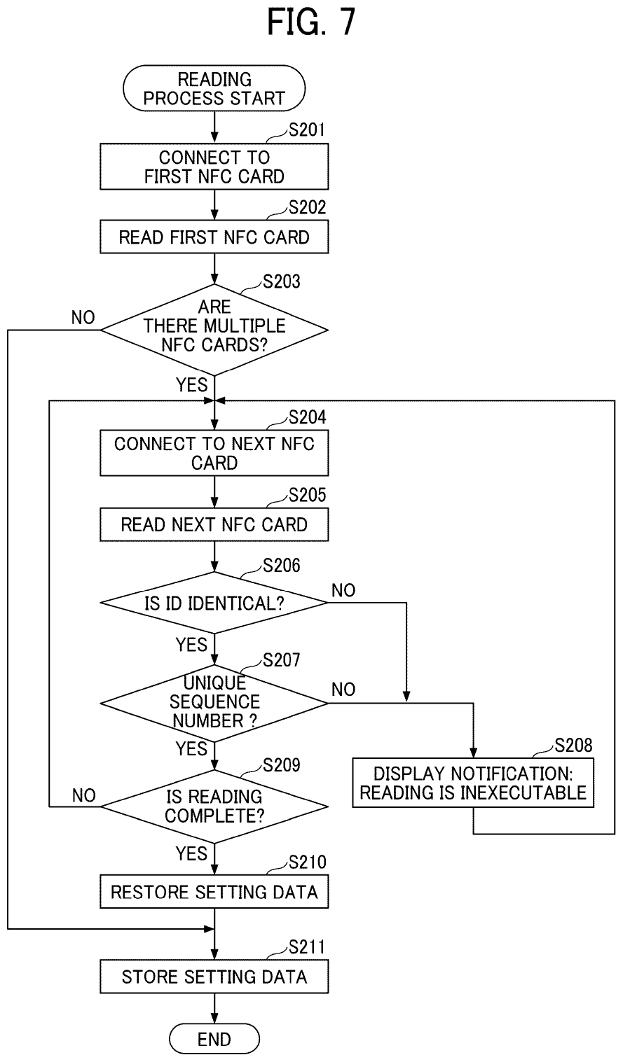

Data Processing Method A data processing method executed by the data processing system 1000 will be described below with reference to FIGS. 5 to 8. The data processing method includes a writing process (see FIG. 5) and a reading process (see FIG. 7). The writing process is a process of writing the setting data to NFC cards. The reading process is a process of reading the setting data from the NFC cards.

### Writing Process

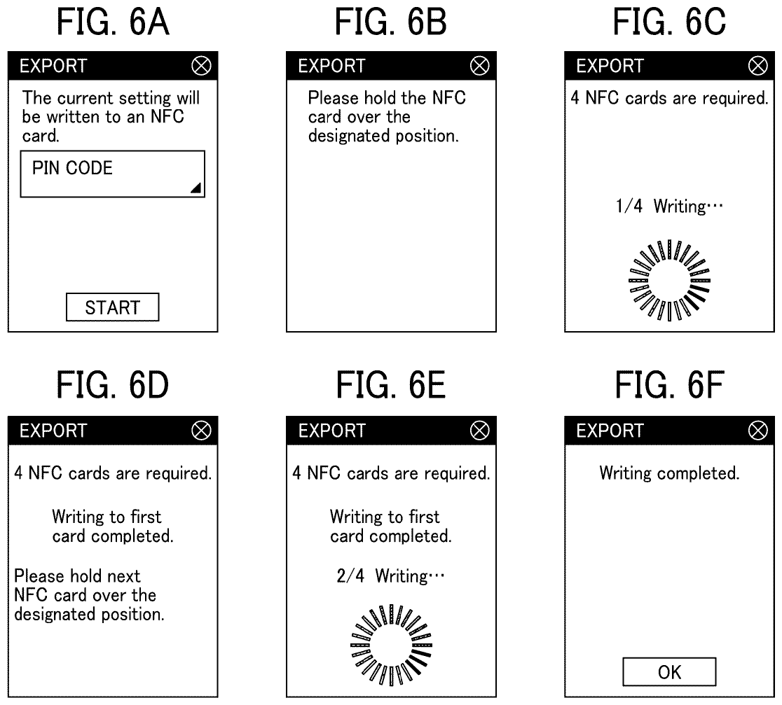

The writing process executed by the controller 100-1 of the scanner 10-1 will be described below with reference to FIGS. 5 and 6. FIG. 5 is a flowchart of the writing process. FIG. 6 is a diagram illustrating an export screen. The export screen is an example of an operation screen in the writing process.

In step S101, the screen display unit 170 of the controller 100-1 displays an export screen. The user performs an operation to start writing the setting data on the export screen. The screen display unit 170 receives the operation to start writing the setting data.

FIG. 6A is a diagram illustrating an export screen displayed when writing the setting data is started. As illustrated in FIG. 6A, the export screen receives the input of a personal identification number (PIN) code, which is an example of authentication information. When the user presses the start button on the export screen, the screen display unit 170 receives the operation to start writing the setting data.

The screen display unit 170 displays on the export screen an instruction to hold the NFC card C over a designated position when receiving the operation to start writing the setting data. The user holds the NFC card C over the designated position of the scanner 10-1. The designated position may be any position where the IC card reader/writer 610 can communicate with the IC chip embedded in the NFC card C via short-range wireless communication.

FIG. 6B is a diagram illustrating an export screen instructing a user to hold the NFC card C over the designated position. When the user holds the NFC card C over the designated position, the IC card reader/writer 610 of the controller 100-1 connects to the NFC card C held over the designated position.

In step S102, the information obtaining unit 110 of the controller 100-1 obtains information indicating the storage capacity of the NFC card C connected in step S101. The information obtaining unit 110 may receive the information indicating the storage capacity from the NFC card C connected in step S101 via short-range wireless communication.

In step S103, the information obtaining unit 110 of the controller 100-1 determines whether the currently connected NFC card C is the first card. For example, the information obtaining unit 110 may store the number of written NFC cards C and determine that the connected NFC card C is the first one when the stored number of written NFC cards C is zero.

When the currently connected NFC card C is the first card (Yes in step S103), the information obtaining unit 110 advances the process to step S104. By contrast, when the connected NFC card C is the second or subsequent card (No in step S103), the information obtaining unit 110 advances the process to step S110.

In step S104, the information obtaining unit 110 of the controller 100-1 obtains information indicating the size of the setting data stored in the data storage unit 101. The information obtaining unit 110 may obtain the data size when the setting data is compressed. When the setting data is compressed and stored in the NFC card C, the total number of NFC cards C used can be reduced.

In step S105, the information obtaining unit 110 of the controller 100-1 calculates the total number of NFC cards C for storing the setting data based on the storage capacity of the NFC cards C and the size of the setting data. Specifically, the information obtaining unit 110 divides the size of the setting data by the storage capacity of the NFC card C and rounds up to the decimal part.

The information obtaining unit 110 determines the size of the data segment based on the total number of the NFC cards C. The splitting unit 120 may determine the size of the data segment such that the size of the data segment is equal to or smaller than the storage capacity of the NFC card C. For example, the information obtaining unit 110 may divide the size of the setting data by the total number of the NFC cards C. The information obtaining unit 110 sends information indicating the size of the data segment to the splitting unit 120.

The screen display unit 170 displays the total number of the NFC cards C on the export screen. The screen display unit 170 further displays the order of the currently written NFC card C on the export screen.

FIG. 6C is a diagram illustrating an export screen displayed while data is written to the first NFC card. As illustrated in FIG. 6C, the export screen may display, for example, a message indicating that four NFC cards are required, and that writing is currently performed on the first one of the four NFC cards.

In step S106, the splitting unit 120 of the controller 100-1 receives information indicating the data size of the data segment from the information obtaining unit 110. The splitting unit 120 reads the setting data from the data storage unit 101.

The splitting unit 120 splits one data segment from an unwritten portion of the setting data. Specifically, the splitting unit 120 obtains an unwritten portion of the setting data corresponding to the size of the data segment from the top. Further, the splitting unit 120 sets the range of the setting data corresponding to the obtained data segment as “written.” When the size of the unwritten portion of the setting data is smaller than the storage capacity of the NFC card C, the splitting unit 120 may obtain the entire unwritten portion as a data segment.

In writing to the first NFC card C, the splitting unit 120 generates identification information used in writing the setting data. In this case, the splitting unit 120 initializes the concatenation sequence information. For example, the splitting unit 120 may initialize the concatenation sequence information to 1. When writing to the second or subsequent NFC card C, the splitting unit 120 updates the concatenation sequence information. For example, the splitting unit 120 may increment the concatenation sequence information. The splitting unit 120 sends the data segment, the identification information, and the concatenation sequence information to the writing unit 130.

In step S107, the writing unit 130 of the controller 100-1 receives the data segment, the identification information, and the concatenation sequence information from the splitting unit 120. The writing unit 130 generates the control information to be associated with the data segment. The control information includes the identification information generated in step S106, the total number of the NFC cards C calculated in step S105, the concatenation sequence information determined in step S106, and the size of the data segment determined in step S104.

In step S108, the writing unit 130 of the controller 100-1 writes the data segment split in step S106 and the control information generated in step S107 to the NFC card C connected in step S101. Specifically, the writing unit 130 stores the control information in the header information of the NFC card C, splits the data segment by a designated number of bytes, and stores the split data in the corresponding blocks of the NFC card C.

In step S109, the writing unit 130 of the controller 100-1 determines whether writing the setting data is complete. For example, the writing unit 130 may increment the number of the NFC cards C with the written setting data and determine that writing the setting data is complete when the number of the NFC cards C with the written setting data is equal to or greater than the total number of the NFC cards C.

When it is determined that writing the setting data is complete (Yes in step S109), the writing unit 130 ends the writing process. By contrast, when it is determined that writing the setting data is not completed (No in step S109), the writing unit 130 returns the process to step S101.

When the process returns to step S101, the screen display unit 170 of the controller 100-1 displays on the export screen a message indicating that writing to the NFC cards C is complete and an instruction to hold the next NFC card C over the designated position. The user holds the next NFC card C over the designated position of the scanner 10-1.

FIG. 6D is a diagram illustrating an export screen instructing the user to hold the next NFC card C over the designated position. As illustrated in FIG. 6D, for example, the export screen may display a message indicating that writing to the first NFC card is complete and an instruction to hold the next NFC card over the designated position. When a user holds the NFC card C over the designated position on the scanner 10-1, the IC card reader/writer 610 of the controller 100-1 connects to the NFC card C held over the designated position.

In step S102, the information obtaining unit 110 obtains information indicating the storage capacity of the connected NFC card C. In step S103, the information obtaining unit 110 determines whether the currently connected NFC card C is the first card. In this case, since the second NFC card C is currently connected, the information obtaining unit 110 advances the process to step S110.

In step S110, the information obtaining unit 110 of the controller 100-1 determines whether the storage capacity of the currently connected NFC card C is sufficient to store the data segment. For example, when the storage capacity of the currently connected NFC card C is equal to or greater than the storage capacity of the first NFC card C, the information obtaining unit 110 may determine that the storage capacity of the NFC card C is sufficient.

When it is determined that the storage capacity of the connected NFC card C is sufficient (Yes in step S110), the information obtaining unit 110 advances the process to step S106. At this time, the screen display unit 170 displays the order of the currently written NFC card C on the export screen. By contrast, when it is determined that the storage capacity of the connected NFC card C is insufficient (No in step S110), the information obtaining unit 110 advances the process to step S111.

FIG. 6E is a diagram illustrating an export screen displayed while data is written to the second NFC card. As illustrated in FIG. 6E, the export screen may display, for example, the message indicating that four NFC cards are required, that writing to one NFC card is complete, and that writing is currently performed on the second one of the four NFC cards.

In step S111, the screen display unit 170 of the controller 100-1 displays a notification indicating that writing to the NFC card C is inexecutable on the export screen. Then, the screen display unit 170 returns the process to step S101. In step S101, the screen display unit 170 displays an instruction to hold another NFC card C over the designated position on the export screen.

In step S106, the splitting unit 120 of the controller 100-1 splits one data segment from an unwritten portion of the setting data. After that, the controller 100-1 executes the process from step S107 to step S109 again on the next data segment. In this manner, the controller 100-1 repeatedly writes the data segment to the NFC cards C until it is determined in step S109 that writing the setting data is complete.

FIG. 6F is a diagram illustrating an export screen displayed when writing the setting data is complete. As illustrated in FIG. 6F, the export screen may display, for example, a message indicating that writing the setting data is complete.

### Reading Process

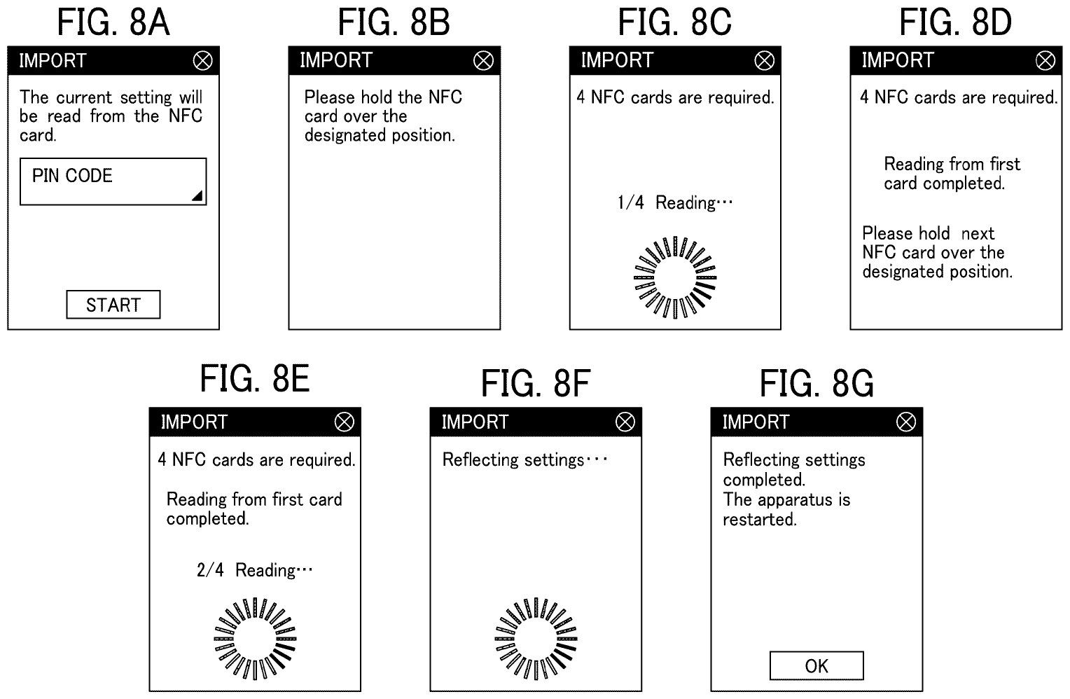

The reading process executed by the controller 100-2 of the scanner 10-2 will be described with reference to FIGS. 7 to 8G. FIG. 7 is a flowchart of the reading process. FIGS. 8a to 8G are diagrams each illustrating an import screen. The import screen is an example of an operation screen in the reading process.

In step S201, the screen display unit 170 of the controller 100-2 displays an import screen. The user performs an operation to start reading the setting data on the import screen. The screen display unit 170 receives the operation to start reading the setting data.

FIG. 8A is a diagram illustrating an import screen displayed when reading the setting data is started. As illustrated in FIG. 8A, the import screen receives the input of a PIN code, which is an example of authentication information. When the user presses the start button on the import screen, the screen display unit 170 performs authentication processing using the PIN code and receives the operation to start reading the setting data when the authentication is successful.

The screen display unit 170 displays on the import screen an instruction to hold the NFC card C over the designated position when receiving the operation to start reading the setting data. The user holds NFC card C over the designated position of the scanner 10-2.

FIG. 8B is a diagram illustrating an import screen instructing the user to hold the NFC card C over the designated position.

When the user holds an NFC card C over the designated position on the scanner 10-2, the IC card reader/writer 610 of the controller 100-2 connects to the NFC card C held over the designated position.

In step S202, the reading unit 140 of the controller 100-2 reads the data segment and the control information from the NFC card C connected in step S201. Specifically, the reading unit 140 reads the control information from the header information of the NFC card C and reads the data segment from the corresponding blocks of the NFC card C.

The screen display unit 170 displays the total number of the NFC cards C indicated in the control information read from the NFC card C on the import screen. The screen display unit 170 further displays the order of the currently read NFC card C on the import screen.

FIG. 8C is a diagram illustrating an import screen displayed while the first NFC card is read. As illustrated in FIG. 8C, the import screen may display, for example, the message indicating that four NFC cards are required and that the first one of the four NFC cards is currently read.

In step S203, the reading unit 140 of the controller 100-2 determines whether there are multiple NFC cards C with the written setting data. The reading unit 140 may determine that there are multiple NFC cards C with the written setting data, for example, when the total number of the NFC cards C indicated in the control information is two or more. Alternatively, the reading unit 140 may determine that there is one NFC card C with the written setting data (in other words, the setting data is written to one NFC card C) when the total number of the NFC cards C indicated in the control information is 1 or less, or when the total number of the NFC cards C is not indicated in the control information.

When it is determined that there are multiple NFC cards C with the written setting data (Yes in step S203), the reading unit 140 advances the process to step S204. By contrast, when it is determined that there is one NFC card C with the written setting data (No in step S203), the reading unit 140 sends one data segment as the setting data to the restoration unit 160, and the process advances to step S211.

In step S204, the screen display unit 170 of the controller 100-2 displays on the import screen a message indicating that reading the NFC card C is complete and an instruction to hold the next NFC card C over the designated position. The user holds the next NFC card C over the designated position of the scanner 10-2.

FIG. 8D is a diagram illustrating an import screen instructing the user to hold the next NFC card C to the designated position. As illustrated in FIG. 8D, the import screen may display, for example, a message indicating that reading the first NFC card is complete and an instruction to hold the next NFC card over the designated position. When the user holds the NFC card C over the designated position on the scanner 10-2, the IC card reader/writer 610 of the controller 100-2 connects to the NFC card C held over the designated position.

In step S205, the reading unit 140 of the controller 100-2 reads the data segment and the control information from the NFC card C connected in step S204. Specifically, the reading unit 140 reads the control information from the header information of the NFC card C and reads the data segment from the corresponding blocks of the NFC card C.

FIG. 8E is a diagram illustrating an import screen displayed while the second NFC card is read. As illustrated in FIG. 8E, the import screen may display, for example, a message indicating that four NFC cards are required and that reading the first NFC card is complete, and that the second one of the four NFC cards is currently read.

In step S206, the determination unit 150 of the controller 100-2 determines whether the identification information in the control information read from the connected NFC card C is identical to that in the control information read from the read NFC card C. When it is determined that the identification information is identical (Yes in step S206), the determination unit 150 advances the process to step S207. By contrast, when it is determined that the identification information is not identical (No in step S206), the determination unit 150 advances the process to step S208.

In step S207, the determination unit 150 of the controller 100-2 determines whether the concatenation sequence information in the control information read from the connected NFC card C is unique or overlaps the concatenation sequence information in the control information read from the read NFC card C. When it is determined that the concatenation sequence information is unique (Yes in step S207), the determination unit 150 advances the process to step S209. By contrast, when it is determined that the concatenation sequence information is not unique (No in step S207), the determination unit 150 advances the process to step S208.

In step S208, the screen display unit 170 of the controller 100-2 displays a notification indicating that reading the NFC card C is inexecutable on the import screen. When it is determined in step S206 that the identification information is not identical, the screen display unit 170 displays on the import screen a notification indicating that an NFC card with inconsistent identification information is read. When it is determined in step S207 that the concatenation sequence information is not unique, the screen display unit 170 displays on the import screen a notification indicating that an identical NFC card is read. Then, the screen display unit 170 deletes the data segment read from the NFC card C and returns the process to step S204. In step S204, the screen display unit 170 displays on the import screen an instruction to hold another NFC card C over the designated position.

In step S209, the reading unit 140 of the controller 100-2 determines whether the data segment or the control information from the read NFC card C satisfies the end condition. When it is determined that the end condition is satisfied (Yes in step S209), the reading unit 140 sends the multiple data segments and the items of control information read from the NFC cards C to the restoration unit 160 and advances the process to step S210. By contrast, when it is determined that the end condition is not satisfied (No in step S209), the reading unit 140 returns the process to step S204.

In step S204, the screen display unit 170 of the controller 100-2 displays on the import screen a message indicating that reading the NFC card C is complete and an instruction to hold the next NFC card C over the designated position. The user holds the next NFC card C over the designated position of the scanner 10-2.

In step S205, the reading unit 140 of the controller 100-2 reads the data segment and the control information from the NFC card C connected in step S204. After that, the controller 100-2 executes the process from step S205 to step S209 again on the next data segment and control information. In this manner, the controller 100-2 repeats reading the data segment and the control information from the NFC cards C until determining in step S209 that reading the setting data is complete.

In step S210, the restoration unit 160 of the controller 100-2 receives the multiple data segments and the items of control information from the reading unit 140. The restoration unit 160 restores the setting data by combining the multiple data segments according to the concatenation sequence information in the control information.

FIG. 8F is a diagram illustrating an import screen displayed while the setting data is restored. As illustrated in FIG. 8F, the import screen may display, for example, a message indicating that the settings are being reflected.

In step S211, the restoration unit 160 of the controller 100-2 stores the setting data in the data storage unit 101. When it is determined in step S203 that there are multiple NFC cards C with the written setting data, the restoration unit 160 stores the restored setting data in the data storage unit 101 in step S210. When it is determined in step S203 that there is one NFC card C with the written setting data, the restoration unit 160 stores the setting data received from the reading unit 140 in the data storage unit 101.

FIG. 8G is a diagram illustrating an import screen displayed when storing the setting data is complete. As illustrated in FIG. 8G, the import screen may display, for example, a message indicating that reflecting the settings is complete. When the user presses the OK button, the controller 100-2 may restart the scanner 10-2 to make the setting data effective.

Aspects of the present disclosure provide the following effects. The controller 100-2 reads electronic data stored in multiple storage media. The controller 100-2 reads multiple data segments split from the electronic data and items of control information each of which indicates the concatenation sequence of the data segment from each of the multiple storage media, and concatenate the multiple data segments read from the storage media according to the sequence indicated in the control information to restore the electronic data. According to one aspect, since the data segment is read from the storage media in any order, the convenience of reading or writing the electronic data from or to the storage media is enhanced.

The controller 100-2 may repeat reading the data segment and the control information from the storage media until the data segment or the control information from the read storage medium satisfies a predetermined end condition. According to one aspect, the controller 100-2 determines whether to end reading the storage media based on the information or data from a read storage medium.

The control information may indicate the total number of storage media with the written data segments. The controller 100-2 may repeat reading the data segment and the control information from the storage media until the number of read storage media reaches the total number of storage media. According to one aspect, whether to end reading the storage media can be properly determined based on the number of the read storage media.

The control information may indicate the size of the electronic data. The controller 100-2 may repeat reading the data segment and the control information from the storage media until the total data size of the data segments from the read storage media matches the size of the electronic data. According to one aspect, whether to end reading the storage media can be properly determined based on the size of the electronic data already read.

The controller 100-2 may repeat reading the data segment and the control information from the storage media until the data segment from the read storage medium contains an end symbol. According to one aspect, whether to end reading the storage medium can be properly determined based on the content of the data segment already read.

The controller 100-2 may display the total number of storage media with written data segments. According to one aspect, the controller 100-2 allows the user to check the number of storage media to be read.

The controller 100-2 may display information on the read storage medium. According to one aspect, the present embodiment allows the user to check information on the read storage medium.

The controller 100-2 may determine whether to read the data segment from the current storage medium based on the control information from the read storage medium. According to one aspect, the reading of electronic data from a wrong storage medium can be prevented.

The controller 100-2 may determine not to read the current storage medium when the sequence indicated in the control information read from the current storage medium overlaps the sequence indicated in the control information read from a read storage medium. According to one aspect, reading the same storage medium multiple times can be prevented.

The control information may indicate identification information identifying a group of storage media. The controller 100-2 may determine not to read the current storage medium when the identification information indicated by the control information read from the current storage medium is different from the identification information indicated by the control information from the storage medium already read. According to one aspect, the reading of a storage medium storing different electronic data is prevented.

The controller 100-1 stores electronic data in multiple storage media. The controller 100-1 splits the electronic data into multiple data segments, associates each data segment with control information that indicates the concatenation sequence of the data segment, and writes the multiple data segments to multiple storage media, respectively. According to one aspect, since the electronic data is read from the storage media in any order, the convenience of reading or writing electronic data from or to the storage media is enhanced.

The storage medium may be a medium from or to which data is read or written via wireless communication. The storage medium may be an NFC card. The electronic data may include the setting data of an electronic device. According to one aspect, the setting data of an electronic device can be read and written using multiple NFC cards.

Each of the above-described functions may be implemented by one or more pieces of processing circuitry. The “processing circuitry” in the present disclosure includes a programmed processor to execute each function by software, such as a processor implemented by an electronic circuit, and a device such as an application-specific integrated circuit (ASIC), a digital signal processor (DSP), a field-programmable gate array (FPGA), and other circuit modules arranged to perform the functions of the above-described embodiments.

The above-described embodiments are illustrative and do not limit the present invention. Thus, numerous additional modifications and variations are possible in light of the above teachings within the scope of the invention indicated in the appended claims.

The disclosed technology has the aspects described below.

(Note 1) A data processing apparatus comprising circuitry configured to:
read a data segment and control information from each of multiple storage media, wherein the data segment is obtained by splitting electronic data, and the control information indicates a concatenation sequence of the data; and
concatenate the data segments individually read from the multiple storage media according to the concatenation sequence indicated in the control information to restore the electronic data.

(Note 2) The data processing apparatus according to Note 1, wherein the circuitry repeats reading the data segment and the control information from the multiple storage media until the read data segment or the read control information from a read storage medium of the multiple storage medium satisfies a predetermined end condition.

(Note 3) The data processing apparatus according to Note 2, wherein
the control information further indicates a total number of the multiple storage media to each of which the data segment is written, and
the circuitry repeats reading the data segment and the control information from the multiple storage media until a number of read storage media matches the total number of the multiple storage media indicated in the control information.

(Note 4) The data processing apparatus according to Note 2, wherein
the control information further indicates a size of the electronic data, and
the circuitry repeats reading the data segment and the control information from the multiple storage media until a total size of the read data segment matches the size of the electronic data.

(Note 5) The data processing apparatus according to Note 2,
wherein the circuitry repeats reading the data segment and the control information from the multiple storage media until an end symbol is included in the data segment read from a read storage medium of the multiple storage media.

(Note 6) The data processing apparatus according to any one of Notes 1 to 5,
wherein the circuitry is further configured to display a total number of the multiple storage media to each of which the data segment is written on a display.

(Note 7) The data processing apparatus according to Note 6,
wherein the circuitry is further configured to display information on a read storage medium of the multiple storage media on the display.

(Note 8) The data processing apparatus according to any one of Notes 1 to 7,
wherein the circuitry is configured to determine whether to read the data segment from a current storage medium based on the control information from a read storage medium of the multiple storage media.

(Note 9) The data processing apparatus according to Note 8,
wherein the circuitry determines not to read the data segment from the current storage medium when the concatenation sequence indicated in the control information read from the current storage medium overlaps the concatenation sequence indicated in the control information read from the read storage medium.

(Note 10) The data processing apparatus according to Note 8, wherein
the control information further indicates identification information identifying a set of the multiple storage media, and
the circuitry determines not to read the data segment from the current storage medium when the identification information indicated by the control information read from the current storage medium differs from the identification information indicated by the control information read from the read storage medium.

(Note 11) A data processing apparatus that stores electronic data in multiple storage media, the apparatus comprising circuitry configured to:
split the electronic data into multiple data segments; and
write the multiple data segments to multiple storage media individually in association with control information indicating a concatenation sequence of the data segment.

(Note 12) The data processing apparatus according to any one of Notes 1 to 11,
wherein the multiple storage media includes a storage medium that allows reading of data and writing of data via wireless communication.

(Note 13) The data processing apparatus according to Note 12, wherein the multiple storage media includes a near field communication card.

(Note 14) The data processing apparatus according to any one of Notes 1 to 13, wherein the electronic data includes setting data of an electronic device.

(Note 15) A method for processing data, the method comprising:
splitting electronic data into multiple data segments by a first data processing apparatus;
writing the multiple data segments to multiple storage media individually in association with control information indicating a concatenation sequence of the data segment by the first data processing apparatus;
reading the data segment and the control information indicating the concatenation sequence of the data segment from each of the multiple storage media by a second data processing apparatus; and
concatenating the data segments read from the multiple storage media according to the concatenation sequence indicated in the control information to restore the electronic data by the second data processing apparatus.

(Note 16) A computer-readable, non-transitory medium storing a computer program, wherein the computer program causes a data processing apparatus that read electronic data from multiple storage media, to execute a process, the process comprising:
reading a data segment and control information from each of the multiple storage media, wherein the data segment is obtained by splitting electronic data, and the control information indicates a concatenation sequence of the data segment; and
concatenating the data segments read from the multiple storage media according to the concatenation sequence indicated in the control information to restore the electronic data.

(Note 17) A computer-readable, non-transitory medium storing a computer program, wherein the computer program causes a data processing apparatus that stores electronic data in multiple storage media, to execute a process, the process comprising:
splitting the electronic data into multiple data segments; and
writing the multiple data segments to multiple storage media individually in association with control information indicating a concatenation sequence of the data segment.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

The functionality of the elements disclosed herein may be implemented using circuitry or processing circuitry which includes general purpose processors, special purpose processors, integrated circuits, application-specific integrated circuits (ASICs), field-programmable gate arrays (FPGAs), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of an FPGA or ASIC.

1. A data processing apparatus comprising circuitry configured to:
read a data segment and control information from each of multiple storage media, wherein the data segment is obtained by splitting electronic data, and the control information indicates a concatenation sequence of the data; and
concatenate the data segments individually read from the multiple storage media according to the concatenation sequence indicated in the control information to restore the electronic data.

2. The data processing apparatus according to claim 1, wherein the circuitry repeats reading the data segment and the control information until the read data segment or the read control information satisfies a predetermined end condition.

3. The data processing apparatus according to claim 2, wherein
the control information further indicates a total number of the multiple storage media to each of which the data segment is written, and
the circuitry repeats reading the data segment and the control information until a number of read storage media matches the total number of the multiple storage media indicated in the control information.

4. The data processing apparatus according to claim 2, wherein
the control information further indicates a size of the electronic data, and
the circuitry repeats reading the data segment and the control information until a total data size of the read data segment matches the size of the electronic data.

5. The data processing apparatus according to claim 2,
wherein the circuitry repeats reading the data segment and the control information until an end symbol is included in the read data segment.

6. The data processing apparatus according to claim 1,
wherein the circuitry is configured to display a total number of the multiple storage media to each of which the data segment is written on a display.

7. The data processing apparatus according to claim 6,
wherein the circuitry is configured to display information on one or more read storage media of the multiple storage media on the display.

8. The data processing apparatus according to claim 1,
wherein the circuitry is configured to determine whether to read the data segment from a current storage medium based on the control information from a read storage medium of the multiple storage media.

9. The data processing apparatus according to claim 8,
wherein the circuitry determines not to read the data segment from the current storage medium when the concatenation sequence indicated in the control information read from the current storage medium overlaps the concatenation sequence indicated in the control information read from the read storage medium.

10. The data processing apparatus according to claim 8, wherein
the control information further indicates identification information identifying a set of the multiple storage media, and
the circuitry determines not to read the data segment from the current storage medium when the identification information indicated by the control information read from the current storage medium differs from the identification information indicated by the control information read from the read storage medium.

11. The data processing apparatus according to claim 1,
wherein the multiple storage media includes a storage medium that allows reading of data and writing of data via wireless communication.

12. The data processing apparatus according to claim 11,
wherein the multiple storage media includes a near field communication card.

13. The data processing apparatus according to claim 1,
wherein the electronic data includes setting data of an electronic device.

14. A method for processing data, the method comprising:
reading a data segment and control information from each of multiple storage media, wherein the data segment is obtained by splitting electronic data, and the control information indicates a concatenation sequence of the data; and
concatenating the data segments individually read from the multiple storage media according to the concatenation sequence indicated in the control information to restore the electronic data.

15. A computer-readable, non-transitory medium storing a computer program, wherein the computer program causes a data processing apparatus that read electronic data from multiple storage media, to execute a process, the process comprising:
reading a data segment and control information from each of the multiple storage media, wherein the data segment is obtained by splitting the electronic data, and the control information indicates a concatenation sequence of the data segment; and
concatenating the data segments read from the multiple storage media according to the concatenation sequence indicated in the control information to restore the electronic data.
